(19) United States
(12) Patent Application Publication
(10) Pub. No.: US 2012/0176680 A1
(43) Pub. Date: Jul. 12, 2012

(54) PATTERNED BACKSIDE OPTICAL COATING ON TRANSPARENT SUBSTRATE

(76) Inventors: Joseph F. Ahadian, San Marcos, CA (US); Charles B. Kuznia, Encinitas, CA (US); Richard T. Hagan, Mission Viejo, CA (US); Richard J. Pommer, Carlsbad, CA (US)

(21) Appl. No.: 13/386,251

(22) PCT Filed: Jul. 19, 2010
(86) PCT No.: PCT/US10/42466

§ 371 Date: Mar. 27, 2012

Related U.S. Application Data
(60) Provisional application No. 61/227,368, filed on Jul. 21, 2009.

(51) Int. Cl. G02B 1/11; B05D 3/14; G03F 7/20; B05D 5/06

(52) U.S. Cl. 359/601; 427/164; 427/532; 430/319

(57) ABSTRACT

A photonic device is described that contains patterns on the backside of a transparent substrate that perform several functions, including anti-reflection coating in certain areas but not in other areas, light blocking in certain areas and not in others. The patterned layers provide improved product performance and improved radiation tolerance.

### CROSS-REFERENCE TO RELATED APPLICATION(S)

This application claims the benefit of U.S. Provisional Patent Application No. 61/227,368, filed Jul. 21, 2009, the contents of which are hereby incorporated by reference in its entirety.

### FIELD

This disclosure is related to the field of integrated circuits and more specifically to photonic integrated circuits with transparent substrates.

### BACKGROUND

As increased demands are placed on data communication rates, the use of photons instead of electrons as a medium for communication has increased. Photonic communication holds the promise of higher speed, lower power, and decreased cross-talk. At each location in a photonic communication system that requires signal processing, the photonic signal content must be converted to electronic signals. This interface between the photonic and electronic worlds requires physical alignment of optical fibers to photodiodes to convert from photonic to electronic signals. It also requires alignment of optical fibers to light generation sources such as vertical cavity surface-emitting lasers (VCSEL's). This interface also opens up possible degradations of the signal and opportunities for noise injection and cross-talk.

Accordingly, methods and systems to address some of the difficulties inherent in photo-to-electro and electro-to-photo connections are an ongoing need in the discipline. Details of improvements as elaborated in the description provided herein are presented below.

### SUMMARY

The following presents a simplified summary in order to provide a basic understanding of some aspects of the claimed subject matter. This summary is not an extensive overview, and is not intended to identify key/critical elements or to delineate the scope of the claimed subject matter. Its purpose is to present some concepts in a simplified form as a prelude to the more detailed description that is presented later.

A photonic device is described that contains discrete patterns on the back side of a transparent substrate that perform several functions. The patterns include anti-reflection coating (ARC) in certain areas but not in other areas, as well as light blocking in certain areas and not in others. The patterned layers provide improved product performance and improved radiation tolerance.

In one aspect of the disclosure, a method for selectively applying a reflective coating on an optical circuit supporting transparent substrate having a front side and a back side is provided, comprising: patterning a first layer having at least one of a front side light reception area and a front side light transmission area on a front side of the substrate, wherein a portion of a non-light reception and non-light transmission areas is designated as a non-photonic circuitry area on the front side of the substrate; patterning a second layer having at least one of a back side light reception area and a back side light transmission area on a back side of the substrate, substantially replicating the corresponding front side light reception area and front side light transmission on the front side of the substrate; and disposing an optical blocking area on the back of the substrate, corresponding to a portion of the non-light reception and non-light transmission areas.

In another aspect of the disclosure, an optical circuit supporting structure is provided, comprising: a transparent substrate having a front side and a back side; a patterned first layer having at least one of a light reception area and a light transmission area disposed on a front side of the substrate, wherein a portion of the non-light reception and non-light transmission areas is designated as a non-photonic circuitry area on the front of the substrate; a patterned second layer having at least one of a light reception area and a light transmission area disposed on a back side of the substrate, substantially replicating the corresponding light reception area and light transmission on the front of the substrate; and an optical blocking area disposed on the back of the substrate, corresponding to a portion of the non-light reception and non-light transmission areas.

In yet another aspect of the disclosure, an optical circuit supporting structure is provided, comprising: means for patterning a first layer having at least one of a front side light reception area and a front side light transmission area on a front side of the substrate, wherein a portion of the non-light reception and non-light transmission areas is designated as a non-photonic circuitry area on the front of the substrate; means for patterning a second layer having at least one of a back side light reception area and a back side light transmission area on a back side of the substrate, substantially replicating the corresponding front side light reception area and front side light transmission on the front of the substrate; and means for disposing an optical blocking area on the back of the substrate, corresponding to a portion of the non-light reception and non-light transmission areas.

These aspects are indicative, however, of but a few of the various ways in which the principles of the claimed subject matter may be employed and the claimed subject matter is intended to include all such aspects and their equivalents. Other advantages and novel features may become apparent from the following detailed description when considered in conjunction with the drawings. As such, other aspects of the disclosure are found throughout the specification.

### BRIEF DESCRIPTION OF THE DRAWINGS

FIG. 1 is a cross-sectional illustration of a related art incoming light system.

FIG. 2 is a cross-sectional illustration of a related art outgoing light system.

FIG. 3 is a cross-sectional illustration of an exemplary integrated system with different back side coatings in different areas of the die.

FIGS. 4A-B are top-view illustrations of a front side and back side, respectively, of an exemplarily treated transparent-substrate die.

FIG. 5 is a cross-sectional illustration of an exemplary substrate receiving ionizing radiation and the effect on charge carriers of an electrical potential on the light blocking layer.

### DETAILED DESCRIPTION

The alignment of optical fibers to electronic circuits is conceptually simple, but in practice is difficult. Such a system is described in U.S. Pat. No. 6,421,474 to Jewell et al, titled “Electro-optical mechanical assembly for coupling a light source or receiver to an optical waveguide.” The use of an integrated circuit with a transparent substrate allows the possibility of bringing in light from the back side of the die, thereby avoiding metallization and structures that are present on the front side of the die that would block light. An example of such a system is described in “A quad 2.7 Gb/s parallel optical transceiver,” by Ahadian, J.; Englekirk, M.; Wong, M.; Li, T.; Hagan, R.; Pommer, R.; Kuznia, C., Radio Frequency Integrated Circuits (RFIC) Symposium, 2004. Digest of Papers. 2004 IEEE, pp. 13-16, 6-8 Jun. 2004. Some areas of the die where outgoing light leaves the transparent die are preferred to have a slightly reflective surface in order to use the reflected light which impinges on an integrated photo-detector to measure average outgoing light intensity. This integrated photo-detector is described in U.S. Pat. No. 6,421,474. Other areas of the die which have transmission of incoming light are preferred to have an anti-reflective coating to maximize the transmission of weak incoming light signals into the high-speed photo-detectors.

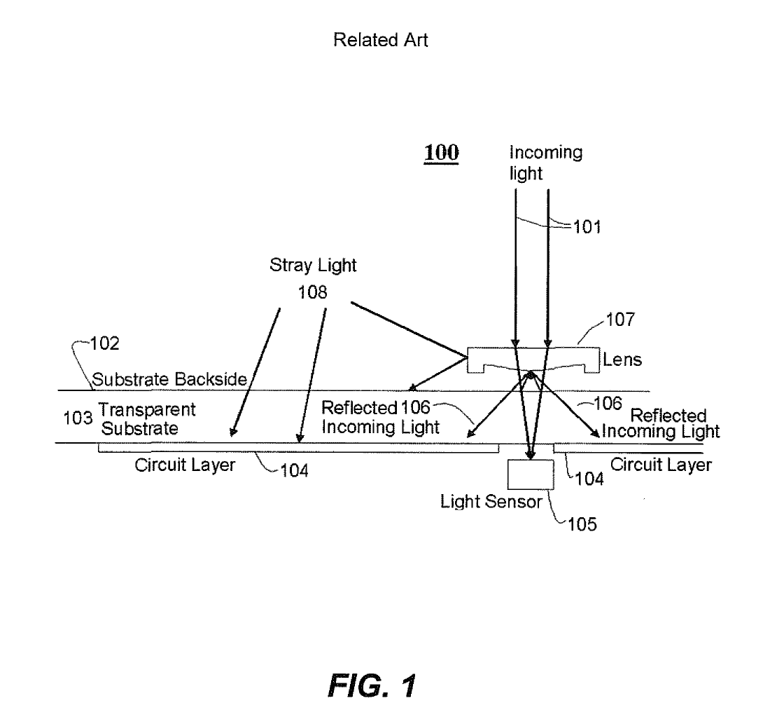

As can be seen in the related art of FIG. 1, drawing 100 shows a cross-section of a simplified system of reception of an external photonic signal onto a device that converts the photonic signal to an electronic signal. The incoming photonic signal 101 passes through a lens 107 which focuses the light onto a light sensor 105 after the light 101 passes through the transparent substrate 103. When the light 101 strikes the back side of the transparent substrate 102, some of the light is reflected from the substrate-to-air interface. Some of that reflected light then reflects a second time, this time from the lens surface. Some of this doubly-reflected light 106 passes a second time through the transparent substrate 103, ultimately falling on the circuit layer 104. Also, stray light 108 may pass through the transparent substrate 103 and also impinge upon the circuit layer 104. Since electronic circuits are inherently able to convert photons to electrons, the reflected light 106 and stray light 108 can cause undesired effects in the circuitry, such as increased noise, change in operating points, or cross-talk between circuits that are intended to be isolated from one another.

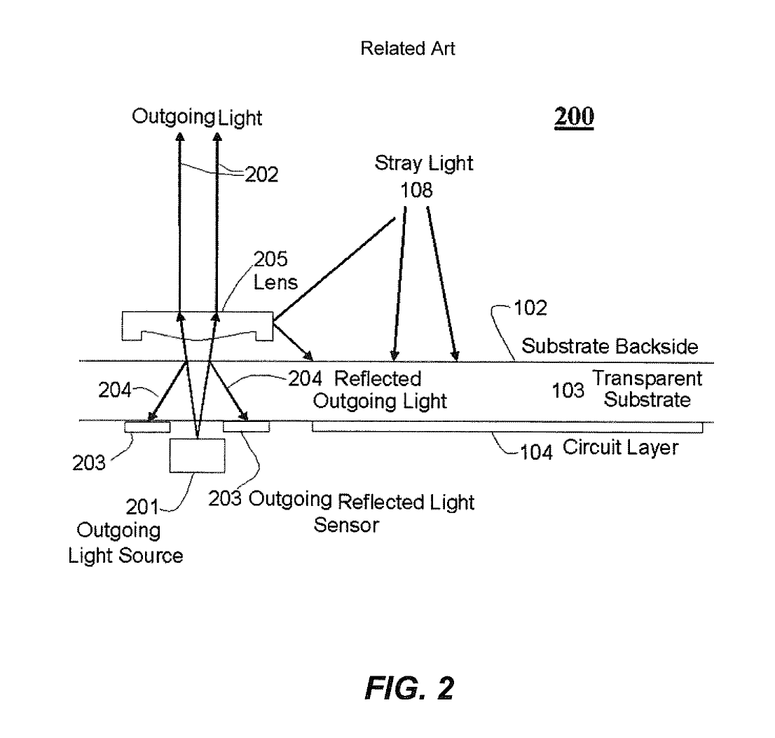

In the system 200 illustrated in FIG. 2, an outgoing light signal 202 can be generated from a source 201 and passed through the transparent substrate 103, a lens 205, and then out to an optical fiber (not shown) for long-distance transmission. When the outgoing light 202 passes through the transparent substrate's back side 102, some of the light may be reflected back toward the circuit-containing side of the substrate or the circuit layer 104 from the air-to-substrate interface. It may be advantageous to place a light sensor 203 at the location where the reflected light 204 will strike the circuit layer side for monitoring purposes. For example, the reflected light sensor 203 may be used to monitor the average power of the outgoing light source by time-averaging the collected signal as is described in U.S. Pat. No. 6,421,474 to Jewell et al.

In view of the above difficulties in the related art, in order to minimize reflection, an anti-reflective coating(s) (ARC) can be placed on the surface of the layer from which reflections are desired to be minimized. However, in such a configuration, the application of an ARC on the transparent substrate's back side 102 in the location where the outgoing light exits the transparent substrate 103 would result in a reduction of minimization of reflected light 204 for detection by the reflected light sensor 203, thereby making it difficult or impossible to monitor optical conditions with this technique.

In addition to signal-containing light, stray light 108 can also impinge on receptors in the transparent substrate systems of 100 and 200. Stray light 108 may come from ambient light such as room light or microscope light during circuit testing or after assembly into a larger system, for example. Stray light 108 may also be reflected and/or refracted light from other signal-containing light paths. Stray light 108 may also be scattered in materials that the light is passing through. Stray light 108 can interact with circuitry, causing degradation of circuit functions such as increased noise, change from desired circuit voltage levels, or cross-talk between signal paths. In view of the difficulties and challenges described above, various exemplary embodiments for methods and systems are described herein that overcome the difficulties of the existing solutions by providing selective ARC patterning.

### ARC

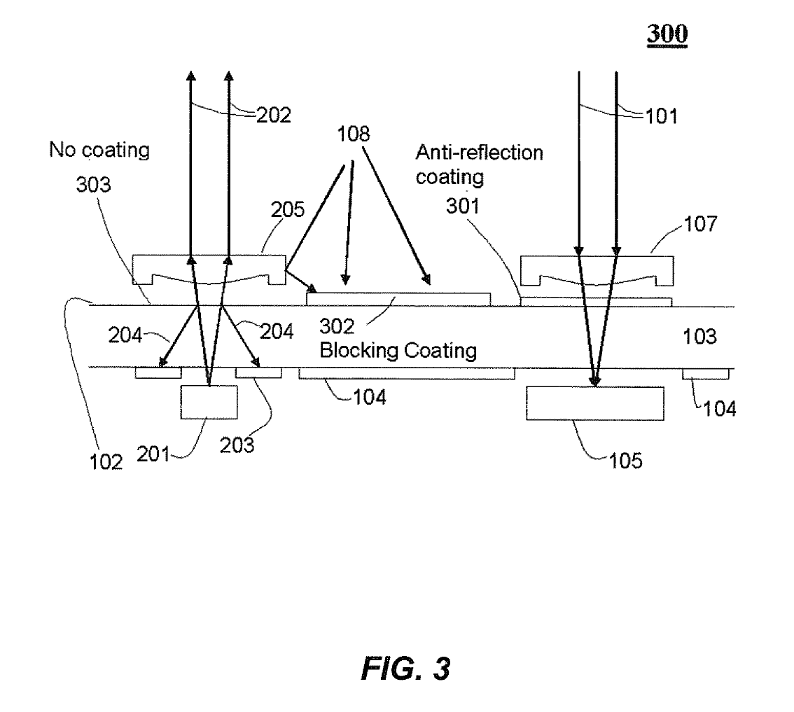

In one of various exemplary embodiments, a method and system of selectively patterning ARC on the back side of a transparent substrate is described. Understanding that a transparent wafer photonics assembly can have several different optical requirements for the back side of the wafer, this ARC can be selectively patterned to judiciously eliminate it from locations where it is not desired. In addition, a blocking layer can also deposited and patterned to remove it only where light is desired to pass through the transparent substrate and, if desired, to provide an electrical potential for improved radiation tolerance. 100211 FIG. 3 is a simplified cross-section drawing of a part of an exemplary integrated photonics assembly 300. In the path of the incoming light 101 which impinges on light receiver 105, an anti-reflection coating 301 is placed on the back side 102 of the transparent wafer 103. Anti-reflection coatings (ARC) are well known to one skilled in the art of optics. The function of the ARC 301 is to minimize the reflection of incoming light 101 from the back side surface 102 of the transparent wafer 103. It is desirable to minimize the reflection of incoming light in order to maximize the optical power received by the light receiver 105. Each loss of light in the optical path reduces the optical power eventually received by the light receiver 105. This results in lower signal to noise ratio of the system, which can result in increased noise in the system. A decreased signal to noise ratio can also reduce the distance that light can travel before it must be boosted by a transceiver, which increases the number of transceivers that a system requires, and therefore increases system cost.

ARC materials can be configured with a different index of refraction from the materials in contact with either side, and often (but not necessarily) have a thickness that is equal to one quarter of the wavelength of the light frequency of interest, resulting in a canceling of the reflected wave and increased transmission of the wave. Typical materials used for optical ARCs are inorganic materials such as MgF₂ (index of refraction n=1.38), CaF₂ (n=1.3 to 1.48), Al₂O₃ (n=1.6), and various other metal oxides, as non-limiting examples. Organic compounds can also be used, and can be commercially purchased from manufacturers such as Brewer Science, for example. As can be appreciated by one skilled in the art, many different materials can serve this purpose well. Accordingly, the materials listed above are provided to show some of many possible applicable materials and are not intended to form an exhaustive list. Therefore, other materials may be used without departing from the spirit and scope of this disclosure.

As shown in FIG. 3, in another part of the optical system 300, there may be a light transmission device 201 which is used to convert electrical signals to photonic signals 202, which may pass through one or more optical components represented by lens 205, and which is then transmitted out of the system. When the photonic signal travels out of the back side 102 of the transparent substrate 103, some of the light 204 is reflected from the transparent wafer back side 102 to a photo-detector 203. This photo-detector 203 uses the reflected light 204 advantageously to monitor the average outgoing optical power and/or energy level. The photo-detector 203 may be an integrated photo-detector (IPD) formed in the circuitry layer 104 on the front side of the wafer, or it may be an external component that is applied to the front of the wafer using a technique such as flip-chip bonding, for example. This reflected light power information can be used in a feedback loop (not shown) to keep the outgoing optical power constant over time, allowing the overall system to respond to environmental changes and aging of the light generation device 201, and so forth. However, since the reflected light 204 is used in this manner, the presence of an ARC on the back side of the wafer 102 in the reflected light 204 transmission path would operate to reduce the reflected light (to the point that it is difficult to measure), which in turn would be detrimental to the information needed for proper reflected light 204 feedback. Therefore, it is sometimes desirable to not have ARC present in those parts of the system, and patterning the ARC is considered as an exemplary approach to achieving selective ARC distribution.

In one exemplary embodiment, a transparent wafer of sapphire (Al₂O₃) has an ARC material of MgF₂ deposited thereupon. MgF₂ can be sputtered onto a transparent wafer using the technique of physical vapor deposition. Other, alternative deposition techniques, such as chemical vapor deposition, sol-gel spin-on, or other suitable techniques can also be used to deposit ARC material. Once the material has been deposited, the technique of photolithography can be used to create a pattern of desired shapes in photo-resist on the back side of the wafer. Because of the optical transparency of a sapphire wafer, alignment of the back side pattern to existing structures on the front of the wafer can be facilitated using photolithography alignment techniques that are known in the semiconductor industry. For example, photo-resist remains in places where it is desired for the MgF₂ to remain. In places where MgF₂ is desired to be removed, photo-resist is removed. A suitable material removal technique can now be used to remove the MgF₂ layer in the exposed areas of the wafer. Several different techniques can be used to remove MgF₂, such as physical sputtering (for example, argon ion sputtering), wet etching (for example nitric acid), plasma etching, or laser-assisted etching (for example, LESAL), and so forth. Because sapphire is resistant to most etchants, removal of the MgF₂ with little damage to the sapphire is possible.

In another exemplary embodiment, the ARC can be deposited over a patterned layer of material which is soluble in a solution that does not etch MgF₂ or the transparent substrate. This so-called “lift-off” technique, then removes the ARC by physically removing the underlying material where the ARC is not desired via lifting off the ARC material from those areas, leaving the ARC where the patterned material was not left. Patterned materials can include photosensitive materials such as photo-resist or polyimide, and so forth. Alternatively, liftoff materials such as SiO₂ can be deposited, photo-resist spun on and patterned, SiO₂ removed where the ARC material is desired to remain, then the photo-resist removed, leaving a pattern of the hard mask. The ARC is applied over the liftoff material, then the lift-off process proceeds as previously described. This process flow is useful when, for example, high-temperature processing is desired after lift-off material patterning that would deform or destroy organic materials like photo-resist or polyimide.

In another exemplary embodiment, the transparent substrate may be glass or quartz, or any suitable transparent material to the “light” being transmitted/received. Either MgF₂ or Al₂O₃ can be used to form an ARC layer on glass or quartz because their index of refraction differs sufficiently from that of glass. Other ARC materials could similarly be used that have an index of refraction different from that of the substrate. Similar techniques of deposition and etch to those described above for the sapphire substrate can be used to pattern the ARC layer with a glass or quartz substrate. It should be appreciated that non-visible light may be utilized with concomitant “transparent” substrates and ARC materials, understanding that these modifications are within the spirit and scope of this disclosure.

In yet another exemplary embodiment, the ARC can be an organic material. The organic ARC can be, in one exemplary embodiment, applied as a liquid to the wafer surface and then dried to form a thin film of material. Organic ARC can be patterned with wet etch, dry etch, or the liftoff technique described elsewhere in this application.

The ARC may be left everywhere except where the IPD is located. In some other cases it may be desirable to leave ARC only where the incoming light passes through the transparent substrate.

### Light-Blocking Layer

Light impinging on circuitry can affect the electrical performance of the circuitry through the generation of current due to the photoelectric effect. Referring back to FIG. 3, because the transparent substrate 103 is transparent to light, light entering from the wafer back side can penetrate through the wafer and impinge on circuitry located on the front side of the wafer 104. Stray light 108 in FIGS. 1-3 can have several different sources in a photonic system. If the system is packaged in an optically transparent housing or is exposed to ambient, then ambient light can impinge on the circuitry. Ambient light could be sunlight, room light, or microscope lights in use during testing and assembly of the system. In addition to ambient light, the photonic signal-containing light source can sometimes reflect off of lenses and other objects in the optical path, or can be scattered by the materials through which the light is passing. This results in loss of signal from the main optical path and also results in stray light in the system. This stray signal-containing light could impinge on another optical path, causing cross-talk between optical paths. Or it can increase the noise level, making it more difficult for the system to extract the signal from the background noise. Therefore, it is desirable to stop undesired light from impinging on front side circuitry layer 104. One method to prevent light from impinging on the front side circuitry layer 104 is to apply a light-blocking layer 302 to the back side of the wafer 102 (as shown in FIG. 3). The presence of a light-blocking layer 302 on the wafer back side 102 would stop any stray light coming from the back side, whether it was ambient light or stray signal-containing light 108. The main characteristic of the light-blocking material of the light blocking layer 302 is that it must block transmission of light at the light wavelengths to which the photo-detectors are sensitive. The light blocking material should be able to withstand the processing temperatures of photonic module manufacturing after deposition. It should also not degrade over the photonic module's designed lifetime in the environments to which it will be exposed. The light-blocking layer should not be present where either incoming light or outgoing light passes through the substrate, therefore, it is patterned.

In one exemplary embodiment, the light-blocking material may be poly-crystalline silicon (polysilicon) deposited using chemical vapor deposition. If the photo-detectors are sensitive to visible light, then a polysilicon film of about 1 μm thickness or more would be sufficient to block substantially all the visible light that impinges on the transparent wafer back side 102 surface. As can be appreciated by one skilled in the art, other materials can be used as light-blocking layers. For example, metal layers commonly used in semiconductor processing, such as aluminum, titanium, titanium nitride, copper, tungsten, or titanium-tungsten alloy would block light transmission very effectively. As another example, of innumerous examples, organic materials with dyes or additives that absorb light of the wavelengths of interest could be used. Standard photolithographic techniques of patterning and etching to those described above can be used to pattern the light-blocking material.

In view of the above explanation, there are several possible alternative sequences of deposition and patterning of the ARC and light blocking layer. In one exemplary sequence, the ARC is deposited and patterned, and then the light-blocking layer is deposited and patterned. In another exemplary sequence, the light-blocking layer is deposited and patterned, and then the ARC is deposited and patterned. In yet another possible exemplary sequence, first the ARC layer is deposited, and then the light-blocking layer is deposited. Then the light-blocking layer is patterned and removed where it is not desired. Next, the ARC layer is removed where it is not desired. In this exemplary sequence, ARC can only be removed in locations where the light-blocking layer has already been removed. In a further possible exemplary sequence, first the light-blocking layer is deposited, then the ARC layer is deposited. Next, the ARC layer is patterned and removed where it is not desired, then the light-blocking layer is patterned and removed where it is not desired. In this exemplary sequence, the light-blocking layer can only be removed in locations where ARC has already been removed. As can be appreciated by one skilled in the art, other variations of the exemplary processing sequences listed above may be defined without departing from the spirit and scope herein.

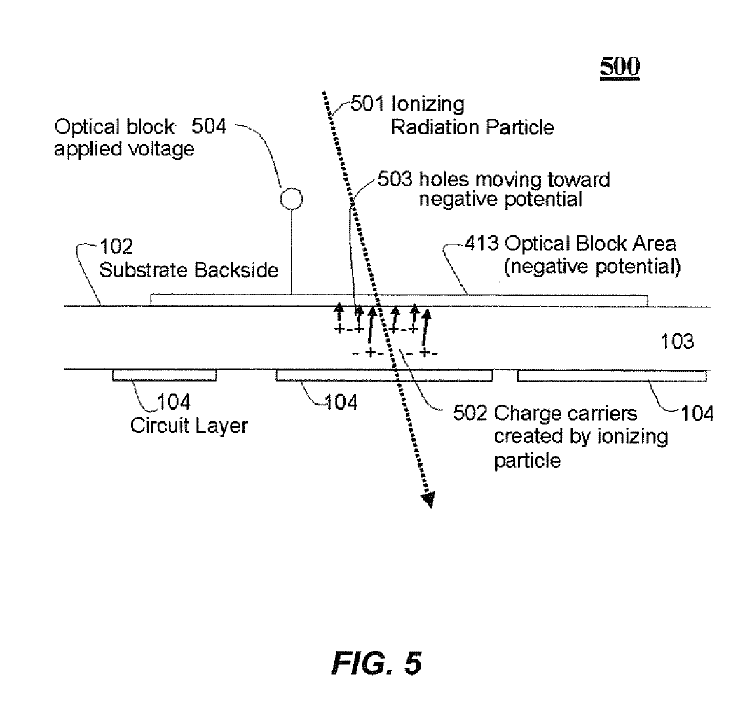

In addition to the function of blocking stray light, a conductive layer on the wafer back side 102 can improve radiation response or provide potential radiation effect improvement. This is thought to happen by providing a sink for holes generated during ionizing radiation, improving the radiation response of a product. This is accomplished by inducing an electric field across the dielectric substrate during irradiation. Referring now to FIG. 5, an ionizing radiation particle 501 passes through the substrate 103. As the radiation particle passes through the substrate 103, electron-hole pairs 502 are created throughout the volume of the substrate 103 and the active layers. A conductive optical block(ing) layer 413 is connected to a potential 504, which is typically (but not necessarily) set to be the most negative potential available on the chip, which is typically electrical ground. Holes 503 are drawn toward the back side of the substrate 102 through electrostatic attraction, away from the active circuitry layer 104. Holes are known to be involved in the formation of electrically active interface states at silicon interfaces with dielectrics. These interface states cause a change in the electrical behavior of active devices, such as transistor threshold voltage shift or increased source-drain leakage. Reducing the number of holes in the front active silicon region reduces the generation of interface states, reducing the radiation-induced electrical shifts in performance. The electrical connection to the conductive optical block layer 413 can be made using any of several well-known methods, depending on the physical placement of the die. For example, wire bonds can be connected to the conductive optical block layer 413; gold bumps or solder bumps could be made that are electrically connected to the conductive optical block layer 413; the conductive optical block layer 413 can be electrically contacted with electrically conductive gluing material like silver filled epoxy, for example. Any suitable method can be used that results in an electrical connection to the conductive optical block layer.

### Example System

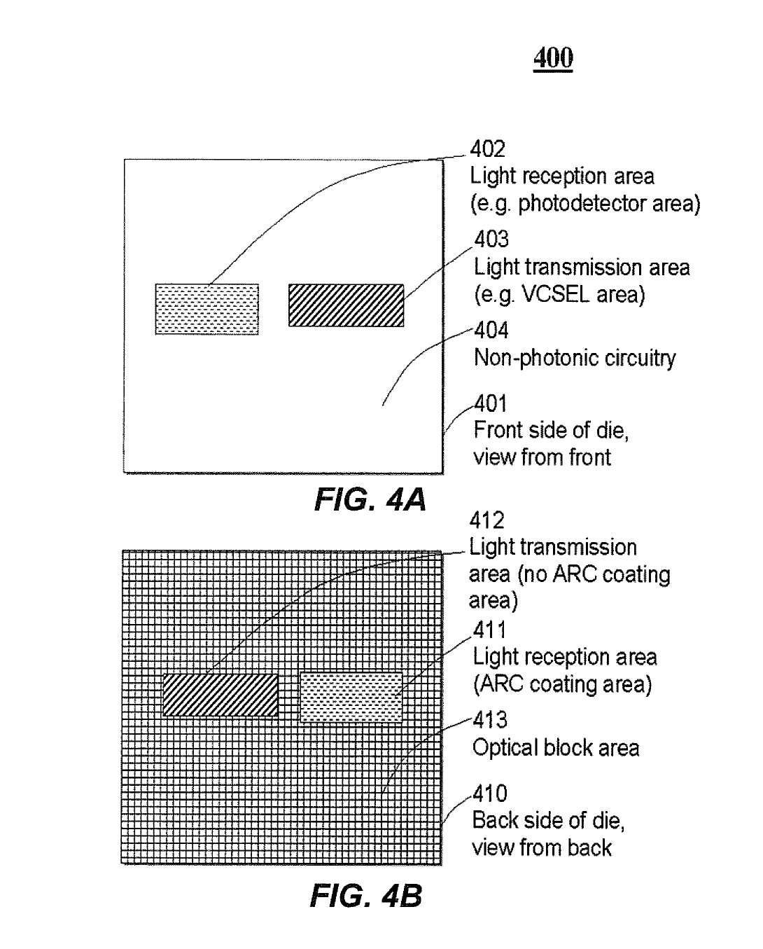

FIGS. 4A-B are top-view illustrations of a front side 401 and back side 410, respectively, of a transparent-substrate die 400. In FIG. 4A, there are three types of areas defined on the front side 401 of the die 400. The light reception area 402 indicates an area of the die 401 where incoming light into the system is sensed. This may be the location where a photo-detector (not shown), for example, can be located. The photo-detector may be surface-mounted on the front side of the transparent substrate die, facing toward the transparent substrate die 400. The light transmission area 403 indicates an area where light is transmitted out from the optical system. It may have, for example, a VCSEL surface mounted on the front side of the die, facing toward the transparent substrate die 400. The non-photonic circuitry area 404 indicates the portion of the die that may have electronic circuitry that does not process optical signals. This is the area that is preferred to be protected from stray light. The various areas shown in FIGS. 4A-B may be altered in shape and also in location, as well as in number. Additionally, the “reverse” sides may be offset or not exact in shape, if so desired, to allow, in some instances, less than exact overlap.

It should be expressly understood that the terms front and back are relative terms and may be interchanged depending on design preference. Therefore, the description of various elements of the exemplary embodiments, having “front” and “back” may be reversed, based on the intents and objectives of the designer. Also, while the embodiments are described in the context of coherent light, non-coherent light or non-visible light (x-ray, infrared, etc.) may be utilized, if applicable. Therefore, the light sources are not constrained to solely being lasers.

In FIG. 4B, the view is of the back side 410 of the transparent substrate die 400. Because it is viewed from the back side 410, the left and right sides of the die 400 are flipped with respect to the respective sides of the front side view 401. The light reception area 411 is the area directly opposite the area where a photo-detector may be mounted 402. In this area, an ARC may be desirable to maximize the efficiency of collection of incoming signal-containing light. The light transmission area 411 is directly opposite the area where a light source (e.g., VCSEL) may be mounted 403. In this area it may be advantageous to not have an ARC layer present in order to allow the advantageous reflection of outgoing light from the transparent substrate back side as described above. The optical block area 413 indicates where optical blocking material may be desired on the transparent substrate back side 410. The optical block area 413 is directly opposite the non-photonic circuitry area 404.

The ARC material and light blocking material can be deposited and patterned at the wafer level before the die are singulated from the wafer. This allows parallel batch processing of all die on the wafer simultaneously, possibly reducing production costs. It is also possible to apply and pattern the ARC and light blocking materials at the die level after the die have been singulated from the wafer.

By coordinating the sequencing and/or arrangement of the respective elements shown, for example, in FIGS. 3 and 4A-B, an increase in efficiency light capture and noise reduction can be achieved for optical systems, specifically for optically transparent substrate-based systems. In combination with the exemplary embodiment described in FIG. 5, significant advances in efficiencies are believed to be obtainable that herethereto have been unknown in the art. In view of the exemplary descriptions provided herein, it should be understood, that based on design objectives and constraints, the various arrangement(s) described can be modified in numerous ways by one of ordinary skill in the art, without departing from the spirit and scope of this disclosure.

As one of several different modifications that can be implemented, the exemplary ARC may be placed in areas that previously would be designed for non-reflection, to now allow reflection, for reasons that may be apparent. Conversely, in some areas where ARC is considered a necessity, it may be expedient or desirable to remove the ARC to allow reflected light to “interfere” on a controlled level, or for other reasons that may be apparent. Thus, numerous modifications may be made by one of ordinary skill in the art, that are within the purview of this disclosure.

What is claimed is:

1. A method for selectively applying a reflective coating on an optical circuit supporting transparent substrate having a front side and a back side, comprising:
patterning a first layer having at least one of a front side light reception area and a front side light transmission area on a front side of the substrate, wherein a portion of a non-light reception and non-light transmission areas is designated as a non-photonic circuitry area on the front side of the substrate;
patterning a second layer having at least one of a back side light reception area and a back side light transmission area on a back side of the substrate, substantially replicating the corresponding front side light reception area and front side light transmission on the front side of the substrate; and
disposing an optical blocking area on the back side of the substrate, corresponding to a portion of the non-light reception and non-light transmission areas.

2. The method of claim 1, wherein the substrate is a sapphire-based substrate.

3. The method of claim 1, further comprising disposing an anti-reflective coating (ARC) in the back side light reception area on the back of the substrate, the ARC being formed from at least one of MgF₂ and Al₂O₃.

4. The method of claim 3, wherein the ARC is at least one of sputtered, vapor deposited, sol-gel spun-on, and photolithographically formed onto the substrate.

5. The method of claim 3, further comprising;
disposing an optical lens on the back side of the substrate and a photo-detector on the front side of the substrate; and
forming the ARC directly beneath the optical lens.

6. The method of claim 5, further comprising forming a circuit layer on the side of the substrate with the photo-detector.

7. The method of claim 3, wherein the optical blocking area is substantially adjacent to the ARC and on an optical lens side of the substrate.

8. The method of claim 1, wherein a portion of the front side and back side light transmission area contains an anti-reflective coating (ARC).

9. The method of claim 1, further comprising applying an applied voltage to a conductive portion of the optical blocking area, to generate a potential radiation effect improvement.

10. An optical circuit supporting structure, comprising:
a transparent substrate having a front side and a back side;
a patterned first layer having at least one of a light reception area and a light transmission area disposed on a front side of the substrate, wherein a portion of a non-light reception and non-light transmission areas is designated as a non-photonic circuitry area on the front side of the substrate;
a patterned second layer having at least one of a light reception area and a light transmission area disposed on the back side of the substrate, substantially replicating the corresponding light reception area and light transmission on the front side of the substrate; and
an optical blocking area disposed on the back side of the substrate, corresponding to a portion of the non-light reception and non-light transmission areas.

11. The optical circuit of claim 10, wherein a portion of the patterned area on the front side of the substrate is substantially identical in size and shape to a portion of the patterned area on the back side of the substrate.

12. The optical circuit of claim 10, wherein the substrate is a sapphire-based substrate.

13. The optical circuit of claim 10, further comprising an anti-reflective coating (ARC) disposed on a light reception area on the back side of the substrate, the ARC being formed from at least one of MgF₂ and Al₂O₃.

14. The optical circuit of claim 13, further comprising an optical lens disposed on the back side of the substrate, wherein the ARC is disposed directly beneath the optical lens.

15. The optical circuit of claim 14, further comprising a circuit layer disposed on the side of the substrate with the photo-detector.

16. The optical circuit of claim 14, wherein the optical blocking area is substantially adjacent to the ARC and on an optical lens side of the substrate.

17. The optical circuit of claim 10, wherein a portion of the front side and back side light transmission area, contains an anti-reflective coating (ARC).

18. The optical circuit of claim 10, further comprising an electrode coupled to a conductive portion of the optical blocking area, to generate a potential radiation effect improvement.

19. An optical circuit supporting structure, comprising:
means for patterning a first layer having at least one of a front side light reception area and a front side light transmission area on a front side of a transparent substrate, wherein a portion of a non-light reception and non-light transmission areas is designated as a non-photonic circuitry area on the front side of the transparent substrate;
means for patterning a second layer having at least one of a back side light reception area and a back side light transmission area on a back side of the transparent substrate, substantially replicating the corresponding front side light reception area and front side light transmission on the front side of the transparent substrate; and
means for disposing an optical blocking area on the back side of the transparent substrate, corresponding to a portion of the non-light reception and non-light transmission areas.

20. The optical circuit of claim 19, further comprising means for anti-reflection of light disposed on the back side light reception area on the back side of the transparent substrate, the means for anti-reflection of light being formed from at least one of MgF₂ and Al₂O₃.

21. The optical circuit of claim 20, further comprising means for focusing light disposed on the back side of the transparent substrate.

22. The optical circuit of claim 20, further comprising means for applying an applied voltage to a conductive portion of the optical blocking area, to generate a potential radiation effect improvement.
